(19) United States
(12) Patent Application Publication
(10) Pub. No.: US 2023/0324467 A1
(43) Pub. Date: Oct. 12, 2023

(54) CONTROL DEVICE FOR SECONDARY BATTERY AND METHOD FOR ESTIMATING FULL CHARGE CAPACITY OF SECONDARY BATTERY

(71) Applicant: TOYOTA JIDOSHA KABUSHIKI KAISHA, Toyota-shi (JP)

(72) Inventors: Kenta ONISHI, Kariya-shi (JP); Mitsuhiro Kuzuba, Kasugai-shi (JP); Yoshihiro Uchida, Nagakute-shi (JP); Yuki Sugo, Toyota-shi (JP)

(73) Assignee: TOYOTA JIDOSHA KABUSHIKI KAISHA, Toyota-shi (JP)

(21) Appl. No.: 18/100,687

(22) Filed: Jan. 24, 2023

(30) Foreign Application Priority Data
Apr. 8, 2022 (JP) 2022-064476

(51) Int. Cl. G01R 31/3842; G01R 31/36

(52) U.S. Cl. CPC G01R 31/3842; G01R 31/3648

(57) ABSTRACT

A battery has an SOC-OCV characteristic having a flat region. When a stage change detecting unit detects an occurrence of stage change during traveling of an electrified vehicle, a discharge current integrating unit calculates a discharge current integrated amount. When external charging is started, a charge current integrating unit calculates a charge current integrated amount until the battery is fully charged. A full charge capacity calculating unit calculates a full charge capacity based on a storage amount at a time of the stage change, the discharge current integrated amount, and the charge current integrated amount.

### CROSS-REFERENCE TO RELATED APPLICATION

This application claims priority to Japanese Patent Application No. 2022-064476 filed on Apr. 8, 2022, incorporated herein by reference in its entirety.

### BACKGROUND

### 1. Technical Field

The present disclosure relates to a control device for a secondary battery and a method for estimating the full charge capacity of the secondary battery.

### 2. Description of Related Art

In Japanese Unexamined Patent Application Publication No. 2014-181924 (JP 2014-181924 A), the full charge capacity of a chargeable battery (secondary battery) is estimated using the state of charge (SOC)-open circuit voltage (OCV) characteristics. In JP 2014-181924 A, in order to estimate the full charge capacity by eliminating the influence of polarization after completion of charging, the full charge capacity of the secondary battery is estimated after eliminating the charge polarization.

### SUMMARY

In the lithium ion battery of an iron phosphate system (LPF system), there is a flat region in which the change rate of the OCV to the SOC is equal to or less than a predetermined value in the SOC-OCV characteristics. This is considered to be because lithium ions enter between the layers of graphite of the negative electrode material to form a stage structure in which lithium ions are regularly occluded for each particular layer. Although the stage structure changes with the change of the storage amount (stage change), when the stage structure is the same, the electrode potential hardly changes even if the storage amount changes and the flat region is generated, whereas the electrode potential changes abruptly when the stage changes.

If the secondary battery has SOC-OCV characteristic having a flat region in which the change rate of the OCV to the SOC is equal to or less than a predetermined value, the ratio of the amount of increase in the OCV to the amount of increase in the SOC in the flat region is very small. Accordingly, in the secondary battery having a flat region in the SOC-OCV characteristics, even if the SOC is calculated using the SOC-OCV characteristics, the calculation accuracy is low. Therefore, even if the full charge capacity is estimated using the SOC-OCV characteristics, the calculation accuracy is low.

An object of the present disclosure is to enable accurate calculation of the full charge capacity even when a secondary battery has SOC-OCV characteristics having a flat region in which the change rate of OCV to SOC is equal to or less than a predetermined value.

A control device for a secondary battery of the present disclosure is a control device for a secondary battery having an SOC-OCV characteristic having a flat region in which a change rate of an open circuit voltage to a state of charge is equal to or less than a predetermined value. A use mode of the secondary battery includes a consumption mode for consuming electric power stored in the secondary battery and a charging mode for charging the secondary battery. The control device includes a stage change detecting unit for detecting an occurrence of a stage change in which a voltage change of the secondary battery is abrupt, while the use mode of the secondary battery is the consumption mode, a storage unit for storing a storage amount at a time of the stage change of the secondary battery, a discharge current integrating unit for integrating current discharged from the secondary battery from when the stage change is detected by the stage change detecting unit until when the consumption mode ends, a charge current integrating unit for integrating current charged to the secondary battery from a start of charging of the secondary battery until the secondary battery is fully charged in the charging mode, and a full charge capacity calculating unit for calculating a full charge capacity of the secondary battery based on the storage amount stored in the storage unit, a discharge current integrated amount integrated by the discharge current integrating unit, and a charge current integrated amount integrated by the charge current integrating unit.

According to this configuration, a use mode of a secondary battery having an SOC-OCV characteristic having a flat region in which a change rate of an open circuit voltage to a state of charge is equal to or less than a predetermined value includes a consumption mode for consuming electric power stored in the secondary battery and a charging mode for charging a power storage device. A stage change detecting unit of a control device detects an occurrence of a stage change in which a voltage change of the secondary battery is abrupt, while the use mode of the secondary battery is the consumption mode. A storage unit stores a storage amount at a time of the stage change of the secondary battery. A discharge current integrating unit integrates current discharged from the secondary battery from when the stage change is detected by the stage change detecting unit until when the consumption mode ends. A charge current integrating unit integrates current charged to the secondary battery from a start of charging of the secondary battery until the secondary battery is fully charged in the charging mode. A full charge capacity calculating unit calculates a full charge capacity based on the storage amount stored in the storage unit, a discharge current integrated amount integrated by the discharge current integrating unit, and a charge current integrated amount integrated by the charge current integrating unit.

In the secondary battery having the SOC-OCV characteristic having the flat region, there is a region in which the voltage (open circuit voltage) of the secondary battery changes abruptly with the change in the storage amount. In the present disclosure, in the flat region, the voltage of the secondary battery changing abruptly with a change in the storage amount (abrupt voltage change of the secondary battery) is referred to as a stage change. In the secondary battery having an SOC-OCV characteristic having a flat region, the storage amount [Ah] when the stage change occurs is substantially the same value regardless of the deterioration state of the secondary battery. The full charge capacity calculating unit calculates the full charge capacity based on the storage amount stored in the storage unit (the storage amount when the stage change occurs) using the discharge current integrated amount and the charge current integrated amount, so that the full charge capacity of the secondary battery can be calculated accurately.

In some embodiments, the full charge capacity calculating unit may calculate a full charge capacity C [Ah] as “C=Y−Z+X”, when the storage amount stored in the storage unit is regarded as X [Ah], the discharge current integrated amount integrated by the discharge current integrating unit is regarded as Z [Ah], and the charge current integrated amount integrated by the charge current integrating unit is regarded as Y [Ah].

According to this configuration, it is possible to directly calculate the full charge capacity using the storage amount, the discharge current integrated amount, and the charge current integrated amount.

A method for estimating a full charge capacity of a secondary battery of the present disclosure is a method for estimating a full charge capacity of a secondary battery having an SOC-OCV characteristic having a flat region in which a change rate of an open circuit voltage to a state of charge is equal to or less than a predetermined value. A use mode of the secondary battery includes a consumption mode for consuming electric power stored in the secondary battery and a charging mode for charging the secondary battery. The method includes acquiring a discharge current integrated amount that is an integrated value of current discharged from the secondary battery, from when a stage change in which a voltage change of the secondary battery is abrupt occurs until when the consumption mode ends in the consumption mode, acquiring a charge current integrated amount that is an integrated value of current charged to the secondary battery, from when charging of the secondary battery is started until when the secondary battery is fully charged in the charging mode, and calculating the full charge capacity of the secondary battery based on a storage amount of the secondary battery when the stage change occurs, the discharge current integrated amount, and the charge current integrated amount.

According to this method, in the secondary battery having the SOC-OCV characteristic having a flat region, since the storage amount [Ah] when the stage change occurs is substantially the same value regardless of the deterioration state of the secondary battery, by calculating the full charge capacity based on the storage amount (storage amount when the stage change occurs) using the discharge current integrated amount and the charge current integrated amount, it is possible to accurately calculate the full charge capacity of the secondary battery.

According to the present disclosure, it is possible to accurately calculate the full charge capacity even when a secondary battery has SOC-OCV characteristics having a flat region in which the change rate of the open circuit voltage (OCV) to the state of charge (SOC) is equal to or less than a predetermined value.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating a schematic configuration of an electrified vehicle according to the present embodiment;

FIG. 2 is a diagram showing an example of state of charge (SOC)-open circuit voltage (OCV) characteristics of a battery according to the present embodiment;

FIG. 3 is a diagram showing an example of the relationship between the OCV and the storage amount of the battery according to the present embodiment;

FIG. 4 is a diagram showing an example of charging and discharging characteristics of the battery according to the present embodiment;

FIG. 5 is a diagram illustrating a functional block configured in a control device;

FIG. 6 is a diagram illustrating an operation of the present embodiment;

FIG. 7 is a flowchart showing an outline of a discharge current integrated amount calculation process executed by the control device; and

FIG. 8 is a flowchart showing an outline of a full charge capacity estimation process executed by the control device.

### DETAILED DESCRIPTION OF EMBODIMENTS

Hereinafter, embodiments of the present disclosure will be described in detail with reference to the drawings. In the embodiments shown below, the same or common parts are denoted by the same reference signs in the drawings, and the description thereof will not be repeated.

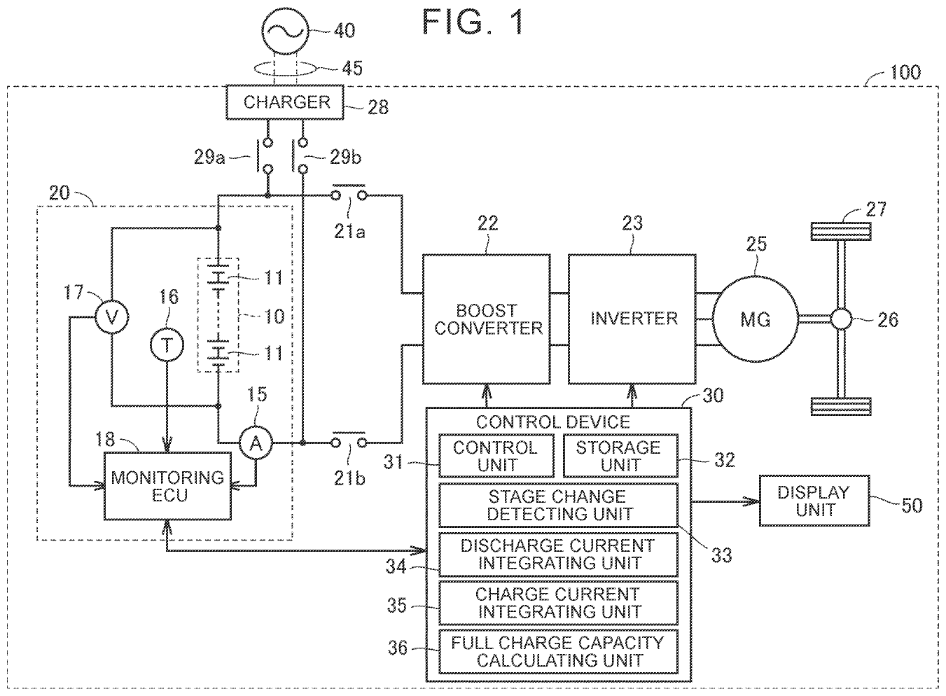

FIG. 1 is a diagram illustrating a schematic configuration of an electrified vehicle 100 according to the present embodiment. In the present embodiment, an example will be described in which the electrified vehicle 100 is a battery electric vehicle (BEV). However, the electrified vehicle 100 is not limited to the BEV, and may be, for example, a plug-in hybrid electric vehicle (PHEV), a hybrid electric vehicle (HEV), a fuel cell electric vehicle (FCEV), or the like.

Referring to FIG. 1, the electrified vehicle 100 includes a battery pack 20, a boost converter 22, an inverter 23, a motor generator 25, a transmission gear 26, drive wheels 27, a control device 30, and a display unit 50.

The battery pack 20 is mounted on the electrified vehicle 100 as a driving power source (i.e., a power source) of the electrified vehicle 100. The battery pack 20 is comprised of a battery (battery module) 10 in which stacks are connected in series. A plurality of cells 11 is stacked in each of the stacks. The cell 11 is comprised of a rechargeable iron phosphate-based lithium-ion battery (LFP battery), for example. In the present embodiment, the stacks are connected in series, but the stacks may be connected in parallel in the battery 10. The battery 10, the cells 11, and the stacks correspond to an example of a “secondary battery” of the present disclosure.

The battery pack 20 further includes a current sensor 15, a temperature sensor 16, a voltage sensor 17, and a battery monitoring unit 18. The battery monitoring unit 18 is constituted by, for example, an electronic control unit (ECU). Hereinafter, the battery monitoring unit 18 is also referred to as “monitoring ECU 18”.

The current sensor 15 detects the input/output current of the battery 10 (hereinafter also referred to as “battery current Ib”). Hereinafter, with respect to the battery current Ib, the discharge current is represented as a positive value, and the charge current is represented as a negative value.

The temperature sensor 16 detects the temperature of the battery 10 (hereinafter also referred to as “battery temperature Tb”). Note that multiple temperature sensors 16 may be disposed. In this case, the weighted average value, the maximum value, or the minimum value of the temperatures detected by the multiple temperature sensors 16 can be used as the battery temperature Tb, or the temperature detected by a specific temperature sensor 16 can be used as the battery temperature Tb. The voltage sensor 17 detects the voltage between terminals of the battery 10 (cell 11) (hereinafter also referred to as “battery voltage Vb”).

The monitoring ECU 18 receives the detected values of the current sensor 15, the temperature sensor 16, and the voltage sensor 17. The monitoring ECU 18 outputs the battery voltage Vb, the battery current Ib, and the battery temperature Tb to the control device 30. Alternatively, the monitoring ECU 18 can store data of the battery voltage Vb, the battery current Ib, and the battery temperature Tb in a built-in memory (not shown).

Further, the monitoring ECU 18 has a function of calculating the state of charge (charge rate) (SOC) of the battery 10 using at least one of the battery voltage Vb, the battery current Ib, and the battery temperature Tb. The calculation function of the SOC can also be provided in the control device 30 to be described later. In this case, an estimation unit for calculating the SOC is provided in the control device 30.

In the following description, data related to the battery 10 such as the battery voltage Vb, the battery current Ib, the battery temperature Tb, and the SOC is collectively referred to as “measurement data”.

The battery 10 is connected to the boost converter 22 via system main relays 21a, 21b. The boost converter 22 boosts the output voltage of the battery 10. The boost converter 22 is connected to the inverter 23, and the inverter 23 converts direct-current (DC) power from the boost converter 22 to alternating-current (AC) power.

The motor generator (three-phase AC motor) 25 generates kinetic energy for causing the electrified vehicle 100 to travel by receiving the AC power from the inverter 23. The kinetic energy generated by the motor generator 25 is transmitted to the drive wheels 27. On the other hand, when decelerating the electrified vehicle 100 or stopping the electrified vehicle 100, the motor generator 25 converts the kinetic energy of the electrified vehicle 100 into electric energy. The AC power generated by the motor generator 25 is converted to DC power by the inverter 23 and supplied to the battery 10 through the boost converter 22. As a result, regenerative power can be stored in the battery 10. In this way, the motor generator 25 is configured to generate a driving force or a braking force of the vehicle with the transfer of electric power to and from the battery 10 (that is, charging/discharging of the battery 10).

Note that the boost converter 22 can be omitted. Further, when using a DC motor as the motor generator 25, the inverter 23 can be omitted.

When the electrified vehicle 100 is configured as a PHEV further equipped with an engine as a power source, the output of the engine can be used as a driving force for traveling in addition to the output of the motor generator 25. It is also possible to generate the charging power of the battery 10 by the engine output using a motor generator that generates electric power by the engine output.

The electrified vehicle 100 is configured to include an external charging function for charging the battery 10 by an external power source 40. The electrified vehicle 100 includes a charger 28 and charging relays 29a, 29b. In the present disclosure, charging of the battery 10 using the external power source 40 is referred to as “external charging”.

The external power source 40 is a power source provided outside the vehicle, and is, for example, a commercial power source. The charger 28 converts electric power from the external power source 40 to the charging power of the battery 10. The charger 28 is connected to the battery 10 via the charging relays 29a, 29b. When the charging relays 29a, 29b are turned on, the battery 10 can be charged by electric power from the external power source 40.

The external power source 40 and the charger 28 can be connected, for example, by charging cables 45. That is, when the charging cables 45 are mounted, the external power source 40 and the charger 28 are electrically connected, which makes it possible to charge the battery 10 using the external power source 40. Alternatively, the electrified vehicle 100 may be configured such that electric power is transmitted in a non-contact manner between the external power source 40 and the charger 28. For example, the battery 10 can be charged by the external power source 40 by transmitting electric power via a power transmitting coil (not shown) on the external power source side and a power receiving coil (not shown) on the electrified vehicle side.

When AC power is supplied from the external power source 40, the charger 28 is configured to have a function of converting the electric power supplied from the external power source 40 (AC power) to the charging power of the battery 10 (DC power). When the external power source 40 is a DC power source, the charger 28 adjusts the magnitude of the DC power from the external power source 40 and supplies the DC power to the battery 10. The mode of the external charging of the electrified vehicle 100 is not particularly limited.

The control device 30 is constituted by, for example, an electronic control unit (ECU), and includes a control unit 31, a storage unit 32, a stage change detecting unit 33, a discharge current integrating unit 34, a charge current integrating unit 35, and a full charge capacity calculating unit 36. The control unit 31 controls the operation of various devices such as the boost converter 22 and the inverter 23.

Programs and various data for operating the control unit 31, the stage change detecting unit 33, and the like are stored in the storage unit 32. The storage unit 32 can be provided outside the control device 30, and data can be read and written in the storage unit 32 by the control unit 31 or the like. Details of the stage change detecting unit 33, the discharge current integrating unit 34, the charge current integrating unit 35, and the full charge capacity calculating unit 36 will be described later.

The control unit 31 of the control device 30 receives signals from various sensors (not shown) such as an accelerator operation amount sensor and a vehicle speed sensor, performs various calculations, and controls the operation of the system main relays 21a, 21b, the boost converter 22, the inverter 23, and the like. When the start switch (power switch) is switched from off to on, the control unit 31 switches the system main relays 21a, 21b from off to on, or operates the boost converter 22 and the inverter 23. When the start switch is switched from on to off, the control device 30 switches the system main relays 21a, 21b from on to off, or stops the operation of the boost converter 22 and the inverter 23. When the external charging is performed, the control unit 31 controls the charger 28 and the charging relays 29a, 29b.

The display unit 50 is configured to display predetermined information to the user of the electrified vehicle 100 in response to a control command from the control device 30. The display unit 50, for example, may be constituted by a touch panel display or the like using a liquid crystal panel.

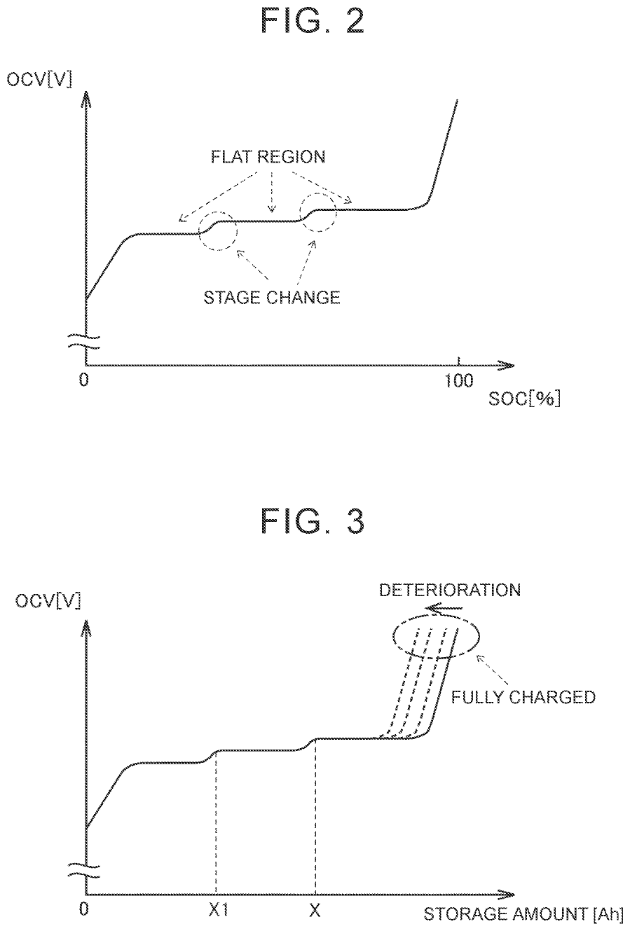

FIG. 2 is a diagram illustrating an example of the SOC-OCV characteristics of the battery 10 (cell 11) according to the present embodiment. For example, when an iron phosphate-based lithium-ion battery is employed as the battery 10 (cell 11), as shown in FIG. 2, the SOC-OCV characteristics have a flat region in which the change rate of the OCV to the SOC is less than a predetermined value. The SOC is a percentage of the current storage amount relative to the full charge capacity of the battery 10. In the flat region, the change rate of the OCV to the SOC is about 0.2 mV/%.

Therefore, even if the SOC is calculated using the SOC-OCV characteristics in the battery (cell) of the flat region in the SOC-OCV characteristics, the calculation accuracy is low. Accordingly, as disclosed in JP 2014-181924 A, even if the SOC is obtained using the SOC-OCV characteristics and the full charge capacity is calculated using this SOC, the full charge capacity of the battery (cell) having the flat region in the SOC-OCV characteristics cannot be calculated accurately.

In the SOC-OCV characteristic of the present embodiment, as shown in FIG. 2, the flat region is divided into three stages. Although the stage structure changes with the change of the storage amount (stage change), when the stage structure is the same, the electrode potential hardly changes even if the storage amount changes, so that a flat region is generated. Since the electrode potential is abruptly changed at the time of stage change, the OCV changes abruptly (the change rate of the OCV becomes larger than a predetermined value), so that a stage change shifting from a flat region to another flat region occurs. In the present embodiment, as shown in FIG. 2, the stage change occurs in two places. In the present disclosure, “stage change” means that, in the SOC-OCV characteristics, the OCV changes abruptly (the change rate of the OCV becomes larger than a predetermined value) to shift from the flat region to the adjacent flat region.

FIG. 3 is a diagram illustrating an example of the relationship between the OCV and the storage amount of the battery 10 (cell 11) according to the present embodiment. In FIG. 3, the vertical axis represents the OCV, and the horizontal axis represents the storage amount [Ah]. In FIG. 3, the solid line shows the relationship between the OCV and the storage amount when the battery 10 (cell 11) is new, and the broken lines show the relationship when the battery 10 is deteriorated. As shown in FIG. 3, even if the battery 10 deteriorates and the storage amount (full charge capacity) at the time of full charge decreases, the storage amount at the time of the stage change does not change, and is substantially the same value when the battery 10 is new and deteriorated.

In the present embodiment, attention is paid to the fact that, even if the battery 10 deteriorates, the storage amount at the time of the stage change is substantially the same value, and the full charge capacity of the battery 10 is accurately calculated based on the storage amount when the stage change occurs.

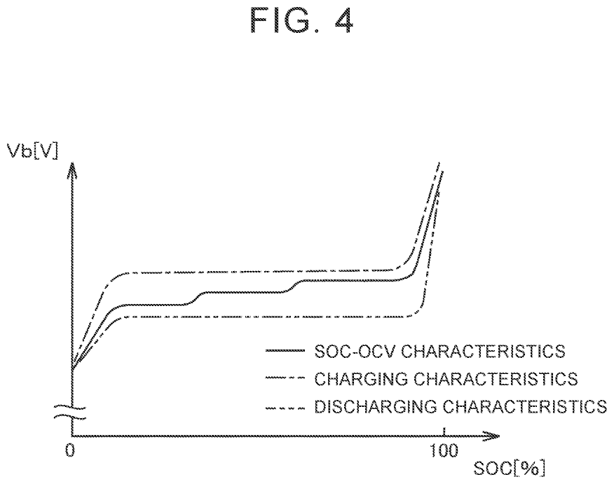

FIG. 4 is a diagram showing an example of the charging and discharging characteristics of the battery 10 (cell 11) according to the present embodiment. In FIG. 4, the vertical axis represents the battery voltage Vb and the horizontal axis represents the SOC. In FIG. 4, the solid line indicates the SOC-OCV characteristics of the battery 10, the long dashed short dashed line indicates charging characteristics when charged with a large current (e.g., charging rate: 2 C) (charging curve), and the long dashed double-short dashed line indicates discharging characteristics when discharged with a large current (e.g., discharge rate: 2 C) (discharging curve). As shown in FIG. 4, when the charge-discharge current is large, an abrupt change in the battery voltage Vb may not appear at the time of the stage change.

In the present embodiment, the stage change of the battery 10 is detected utilizing the fact that when the electrified vehicle 100 is traveling, the frequency of the traveling state in which the discharge rate of the battery 10 is relatively small (e.g., during steady traveling) is high.

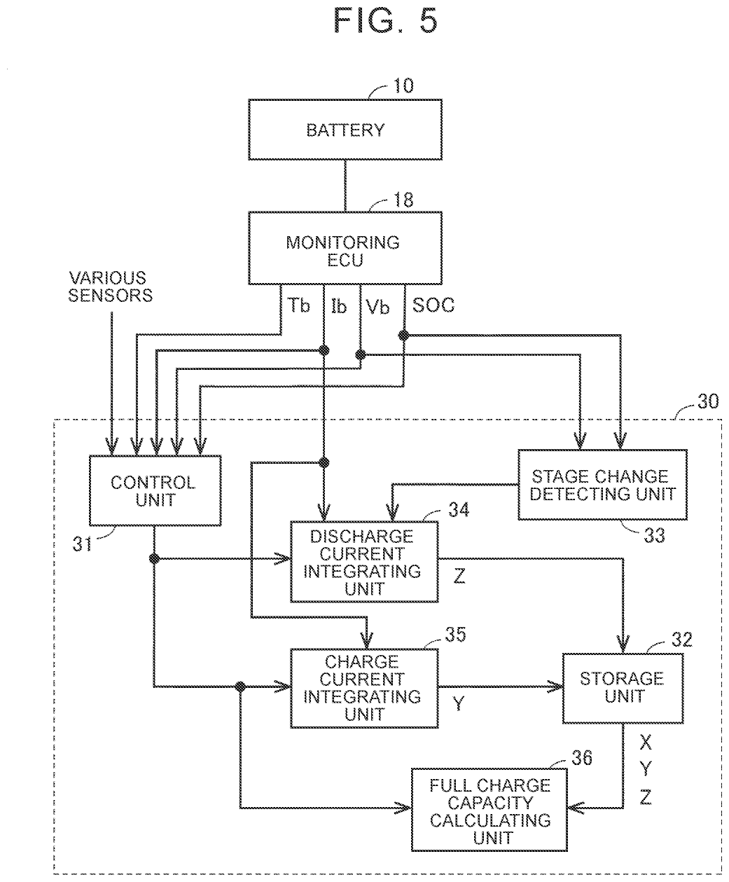

FIG. 5 is a diagram illustrating a functional block configured in the control device 30. As described above, the control unit 31 performs a predetermined calculation using signals from the various sensors and the measurement data from the monitoring ECU 18, and controls the inverter 23, the charger 28, and the like to control the traveling state and the external charging of the electrified vehicle 100.

The electrified vehicle 100 is a BEV, and the battery 10 is charged by the regenerative power during braking or downhill traveling, but the regenerative power is less than the electric power consumed during traveling. Therefore, when the electrified vehicle 100 is traveling, the SOC of the battery 10 decreases. The traveling state of the electrified vehicle 100 corresponds to an example of a “consumption mode for consuming electric power stored in a secondary battery” in the present disclosure. In the present disclosure, the traveling state of the electrified vehicle 100, which is the state between the time when the start switch (power switch) is turned on and the time when the start switch is turned off, is the state when the electrified vehicle 100 can travel.

In the storage unit 32, the storage amount X [Ah] at the time of the stage change of the battery 10 (cell 11) is stored. In the battery 10 (cell 11) of the present embodiment, as shown in FIG. 3, the stage change occurs in two places. In the present embodiment, the storage amount X at the time of the stage change of the larger storage amount (larger SOC) is stored in the storage unit 32. The storage amount X at the time of the stage change is obtained in advance by experiments or simulations, and is stored in the storage unit 32.

The stage change detecting unit 33 detects the occurrence of a stage change in which the voltage change of the battery 10 is abrupt during traveling of the electrified vehicle 100. In the present embodiment, the occurrence of the stage change of the larger storage amount (larger SOC) is detected. For example, in FIG. 3 (FIG. 2), when the stage change of the larger storage amount (larger SOC) occurs in the region in which the SOC is 50% or more and the stage change of the smaller storage amount (smaller SOC) occurs in the region in which the SOC is less than 50%, the stage change detecting unit 33 monitors the differential value ΔVb of the battery voltage Vb and the SOC during traveling of the electrified vehicle 100. When the differential value ΔVb in the region in which the SOC is 50% becomes equal to or larger than the predetermined value α, the occurrence of the stage change is detected and a detection signal of the stage change is output to the discharge current integrating unit 34.

Upon receiving the detection signal of the stage change from the stage change detecting unit 33, the discharge current integrating unit 34 uses the battery current Ib to start integrating the discharge current from the battery 10. Regarding the battery current Ib, since the discharge current is a positive value and the charge current is a negative value, the discharge current integrated amount Z [Ah] that is an integrated value of the discharge current decreases when the battery 10 is charged by the regenerative power, but increases with the decrease in the SOC. Upon receiving a notification from the control unit 31 that the start switch is turned off and the traveling of the electrified vehicle 100 is terminated, the discharge current integrating unit 34 ends the integration of the discharge current from the battery 10 and stores the discharge current integrated amount Z [Ah] in the storage unit 32. The discharge current integrated amount Z [Ah] is the storage amount [Ah] discharged from the battery 10 from the time when the stage change is detected by the stage change detecting unit 33 until the time when the traveling of the electrified vehicle 100 is terminated (until the consumption mode is terminated).

When the charging cable 45 is connected and the external charging is started, the control unit 31 notifies the charge current integrating unit 35 of the start of the external charging. When the external charging of the battery 10 is started, the charge current integrating unit 35 uses the battery current Ib to start integrating the charging current to the battery 10. When the battery 10 is fully charged and the external charging is terminated, the charge current integrating unit 35 terminates the integration of the charge current and stores the charge current integrated amount Y [Ah], which is an integrated value of the charge current, in the storage unit 32. The battery current Ib is a negative value because it is the charge current, but the sign is inverted for the charge current integrated amount Y [Ah] and the charge current integrated amount Y [Ah] is stored as a positive value. When the battery voltage Vb becomes a value corresponding to the full charge, the control unit 31 turns off (releases) the charging relays 29a, 29b to stop the operation of the charger 28, and notifies the charge current integrating unit 35 of the termination of the external charging. When the SOC of the battery 10 becomes a value indicating full charge (e.g., 90%), the control unit 31 may terminate the external charging. In some embodiments, the value of the battery voltage Vb corresponding to the full charge and the value of the SOC indicating the full charge are a value after the battery voltage Vb/OCV has risen (suddenly increased) in the vicinity of the full charge of the battery 10 (cell 11).

The full charge capacity calculating unit 36 calculates the full charge capacity C of the battery 10 (cell 11). The full charge capacity calculating unit 36 reads the storage amount X [Ah] at the time of the stage change, the discharge current integrated amount Z [Ah], and the charge current integrated amount Y [Ah] from the storage unit 32. The full charge capacity calculating unit 36 then calculates the full charge capacity C [Ah] as “C=Y−Z+X”. The full charge capacity C is the storage amount [Ah] when the battery 10 (cell 11) is fully charged.

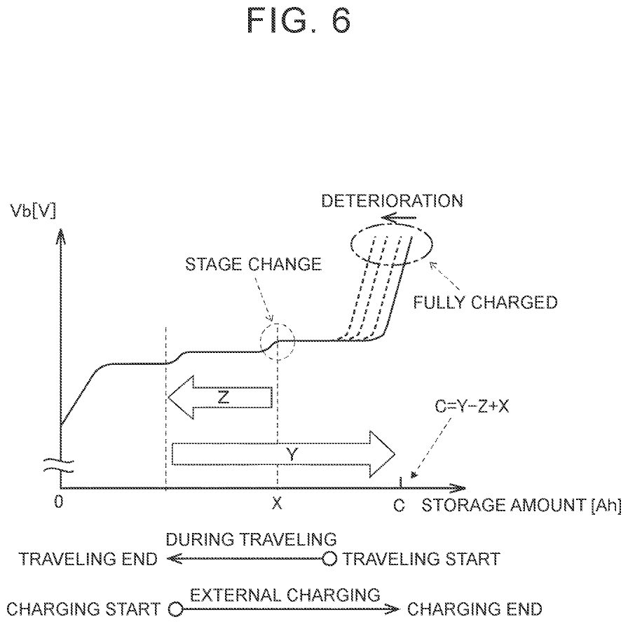

FIG. 6 is a diagram illustrating the operation of the present embodiment. Referring to FIG. 6, when the start switch (power switch) of the electrified vehicle 100 is turned on and the traveling starts, the storage amount/SOC of the battery 10 decreases (the use mode of the battery 10 is changed to the consumption mode). While the storage amount/SOC of the battery 10 decreases, when a stage change in which the change in the battery voltage Vb is abrupt and the differential value ΔVb is equal to or larger than a predetermined value occurs in a region in which the SOC is 50% or more, the stage change detecting unit 33 detects the occurrence of the stage change.

The discharge current integrating unit 34 uses the battery current Ib to integrate the discharge current discharged from the battery 10, from the time when the stage change is detected until the time when the start switch (power switch) is turned off and the traveling of the electrified vehicle 100 is terminated (until the consumption mode is terminated). Then, the discharge current integrating unit 34 stores the discharge current integrated amount Z [Ah], which is an integrated value of the discharge current, in the storage unit 32.

When the external charging is started, the charge current integrating unit 35 uses the battery current Ib to start integrating the charge current to be charged to the battery 10. When the battery 10 is fully charged and the external charging is terminated, the charge current integrating unit 35 terminates the integration of the charge current. Then, the charge current integrating unit 35 stores the charge current integrated amount Y [Ah], which is an integrated value of the charge current, in the storage unit 32.

The full charge capacity calculating unit 36 reads the storage amount X [Ah] at the time of the stage change, the discharge current integrated amount Z [Ah], and the charge current integrated amount Y [Ah] from the storage unit 32 and calculates the full charge capacity C [Ah] as “C=Y−Z+X”. The storage amount X [Ah] at the time of the stage change is substantially the same value when the battery 10 is new and deteriorated. Therefore, by using the discharge current integrated amount Z [Ah] and the charge current integrated amount Y [Ah] based on the storage amount X [Ah] when the stage change occurs, the full charge capacity C [Ah] calculated as “C=Y−Z+X” accurately represents the full charge capacity of the battery 10 (cell 11).

The stage change detecting unit 33 detects the occurrence of the stage change during traveling of the electrified vehicle 100. Since the frequency of the state in which the discharge current is small (C rate is small) is relatively high during traveling of the electrified vehicle 100, it is possible to reliably detect the occurrence of the stage change.

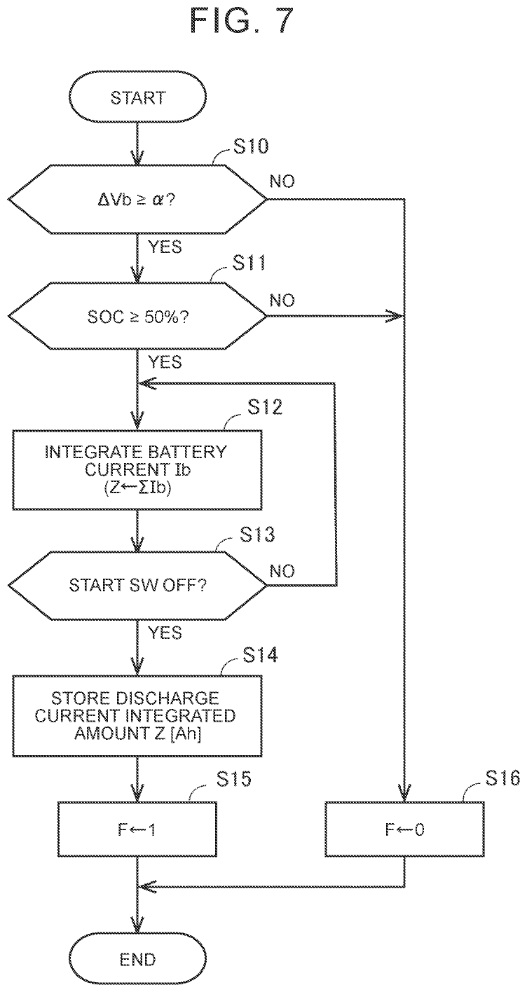

An outline of the control to be processed by the control device 30 in the present embodiment will be described. FIG. 7 is a flowchart showing an outline of a discharge current integrated amount calculation process executed by the control device 30. This flowchart is repeatedly processed at predetermined time intervals when the start switch of the electrified vehicle 100 (power switch) is turned on. First, in step (hereinafter, step is abbreviated as S) 10, it is determined whether the differential value ΔVb of the battery voltage Vb detected by the voltage sensor 17 is equal to or larger than a predetermined value α. The predetermined value α is a threshold value for determining whether the stage change has occurred, and is set in advance by experiments or the like. When the stage change occurs, the differential value ΔVb becomes equal to or larger than the predetermined value a, so that an affirmative determination is made in S10 and the process proceeds to S11. When the differential value ΔVb is less than the predetermined value α, the stage change has not occurred, so that a negative determination is made and the process proceeds to S16.

In S11, it is determined whether the SOC is 50% or more, and when the SOC is 50% or more, an affirmative determination is made and the process proceeds to S12, and when the SOC is less than 50%, a negative determination is made and the process proceeds to S16.

In S12, since an affirmative determination is made in S10 and S11 and the stage change of the larger storage amount (larger SOC) is detected, the discharge current is integrated by integrating the battery current Ib. Then, the process proceeds to S13, and it is determined whether the start switch (power switch) is turned off. In S13, when the start switch is not turned off, the process returns to S12 and continues the integration of the discharge current using the battery current Ib. When the start switch is turned off, an affirmative determination is made in S13 and the process proceeds to S14.

In S14, the discharge current integrated in S12 is stored in the storage unit 32 as the discharge current integrated amount Z [Ah], and the process proceeds to S15. In S15, after setting the flag F to 1, the present routine ends.

When a negative determination is made in S10 or S11, and the process proceeds to S16, after setting the flag F to 0, the present routine ends.

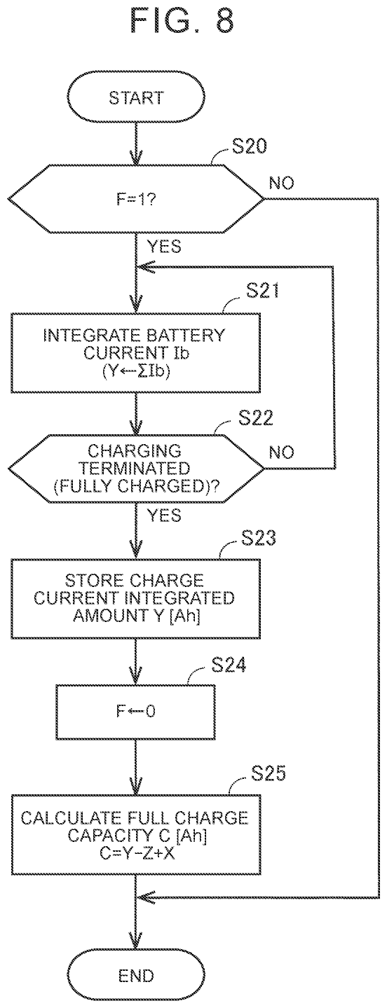

FIG. 8 is a flowchart showing an outline of a full charge capacity estimation process executed by the control device 30. This flowchart is executed when the charging cable 45 is connected and the external charging is started. In step S20, it is determined whether the flag F is 1. When the flag F is 1, an affirmative determination is made and the process proceeds to S21. When the flag F is 0, a negative determination is made and the present routine ends.

In S21, by integrating the battery current Ib, the charge current is integrated. Then, the process proceeds to S22, and it is determined whether the battery 10 is fully charged and the external charging is terminated. When the external charging is not terminated, a negative determination is made and the process returns to S21, and the integration of the charge current is continued using the battery current Ib. When the external charging is terminated, an affirmative determination is made in S22 and the process proceeds to S23.

In S23, the charge current integrated in S22 is stored in the storage unit 32 as the charge current integrated amount Y [Ah], and the process proceeds to S24. In S24, after setting the flag F to 0, the process proceeds to S25.

In S25, the storage amount X [Ah] at the time of the stage change, the discharge current integrated amount Z [Ah], and the charge current integrated amount Y [Ah] are read from the storage unit 32, and after calculating the full charge capacity C [Ah] as “C=Y−Z+X”, the present routine ends.

In the above embodiment, the occurrence of the stage change of the larger storage amount (larger SOC) is detected. However, the occurrence of the stage change of the smaller storage amount (smaller SOC) may be detected, and the full charge capacity C may be calculated based on the storage amount at the time of the above stage change (in FIG. 3, X1 [Ah]).

In the above embodiment, the charge current integrated amount Y [Ah] at the time of the external charging is obtained. However, when the PHEV is used as the electrified vehicle, after the SOC reaches the lower limit value during traveling of the PHEV, forced charging may be performed until the battery is fully charged, and the charge current integrated amount Y [Ah] may be calculated by integrating the battery current Ib in the forced charging.

In the above embodiment, the stage change detecting unit 33 detects the occurrence of the stage change in which the voltage change of the battery 10 is abrupt during traveling of the electrified vehicle 100. In the case of a configuration in which the electric power of the battery 10 is used as the charging power of an auxiliary battery or a configuration in which the auxiliary load such as an electric air conditioner is driven using the electric power of the battery 10, the stage change detecting unit 33 may detect the occurrence of the stage change in which the voltage change of the battery 10 is abrupt while the discharge from the battery 10 to these auxiliary devices is being performed. In this case, the discharge current integrating unit 34 integrates the discharge current to these auxiliary devices.

In the case where the electrified vehicle 100 has a charging and discharging device in place of or in addition to the charger 28 and is capable of discharging from the battery 10 to a household load or a power system, the stage change detecting unit 33 may detect the occurrence of the stage change in which the voltage change of the battery 10 is abrupt while discharging to the household load is being performed or while discharging to the power system (reverse power flow) is being performed. In this case, the discharge current integrating unit 34 integrates the discharge current to the household load or the power system.

In the above embodiment, the stage change detecting unit 33 detects the occurrence of the stage change when the differential value ΔVb of the battery voltage Vb becomes equal to or larger than the predetermined value α, and outputs a detection signal of the stage change to the discharge current integrating unit 34. However, detection method of the occurrence of the stage change is not limited to this. For example, the battery voltage at the time of the occurrence of the stage change under various conditions such as the temperature and the degree of deterioration of the battery 10 may be stored in a map or the like, and the occurrence of the stage change may be detected using this map.

To illustrate embodiments in the present disclosure, the following aspects can be illustrated.
1) Provided is a control device for a secondary battery (10) having an SOC-OCV characteristic having a flat region in which a change rate of an open circuit voltage to a state of charge is equal to or less than a predetermined value. A use mode of the secondary battery (10) includes a consumption mode for consuming electric power stored in the secondary battery (10) and a charging mode for charging the secondary battery (10). The control device (30) includes a stage change detecting unit (33) for detecting an occurrence of a stage change in which a voltage change of the secondary battery (10) is abrupt, while the use mode of the secondary battery (10) is the consumption mode, a storage unit (32) for storing a storage amount X at a time of the stage change of the secondary battery (10), a discharge current integrating unit (34) for integrating current discharged from the secondary battery (10) from when the stage change is detected by the stage change detecting unit (33) until when the consumption mode ends, a charge current integrating unit (35) for integrating current charged to the secondary battery (10) from a start of charging of the secondary battery (10) until the secondary battery (10) is fully charged in the charging mode, and a full charge capacity calculating unit (36) for calculating a full charge capacity C of the secondary battery (10) based on the storage amount X stored in the storage unit (32), a discharge current integrated amount Z integrated by the discharge current integrating unit (34), and a charge current integrated amount Y integrated by the charge current integrating unit (35).
2) In the above 1, the secondary battery (10) is a power source mounted on an electrified vehicle (100), the consumption mode is a mode during traveling of the electrified vehicle (100) using electric power of the secondary battery (10), and the charging mode is a mode while external charging of the secondary battery (10) is being performed.

The stage change of the secondary battery (abrupt voltage change of the secondary battery due to the change of the storage amount) does not show a remarkable tendency when the charge-discharge current is large. In this configuration, the stage change detecting unit detects the occurrence of the stage change during traveling of the electrified vehicle (consumption mode). Since the frequency of the state where the discharge current is small (C rate is small) is relatively high during traveling of the electrified vehicle, the stage change detecting unit can reliably detect the occurrence of the stage change. In the case of a configuration in which the electric power of the secondary battery is used as the charging power of the auxiliary battery, or in the case of a configuration in which the auxiliary load of the electric air conditioner or the like is driven using the electric power of the secondary battery, the state during the traveling of the electrified vehicle includes a state in which the electric power consumption is performed by these auxiliary devices.
3) In the above 1 or 2, the stage change detecting unit (33) detects the occurrence of the stage change when a differential value (ΔVb) of a voltage of the secondary battery (10) is equal to or larger than a predetermined value.
4) In the above 1 to 3, the full charge capacity calculating unit (36) calculates the full charge capacity C as “full charge capacity C=charge current integrated amount Y−discharge current integrated amount Z+storage amount X”.

The embodiments disclosed herein are illustrative in all respects and not restrictive. The scope of the present disclosure is indicated by the appended claims and includes all changes within the meaning and range of equivalency of the claims.

What is claimed is:

1. A control device for a secondary battery having an SOC-OCV characteristic having a flat region in which a change rate of an open circuit voltage to a state of charge is equal to or less than a predetermined value, wherein:
a use mode of the secondary battery includes a consumption mode for consuming electric power stored in the secondary battery and a charging mode for charging the secondary battery; and
the control device includes
a stage change detecting unit for detecting an occurrence of a stage change in which a voltage change of the secondary battery is abrupt, while the use mode of the secondary battery is the consumption mode,
a storage unit for storing a storage amount at a time of the stage change of the secondary battery,
a discharge current integrating unit for integrating current discharged from the secondary battery from when the stage change is detected by the stage change detecting unit until when the consumption mode ends,
a charge current integrating unit for integrating current charged to the secondary battery from a start of charging of the secondary battery until the secondary battery is fully charged in the charging mode, and
a full charge capacity calculating unit for calculating a full charge capacity of the secondary battery based on the storage amount stored in the storage unit, a discharge current integrated amount integrated by the discharge current integrating unit, and a charge current integrated amount integrated by the charge current integrating unit.

2. The control device according to claim 1, wherein the full charge capacity calculating unit calculates a full charge capacity C [Ah] of the secondary battery as “C=Y−Z+X”, when the storage amount stored in the storage unit is regarded as X [Ah], the discharge current integrated amount integrated by the discharge current integrating unit is regarded as Z [Ah], and the charge current integrated amount integrated by the charge current integrating unit is regarded as Y [Ah].

3. A method for estimating a full charge capacity of a secondary battery having an SOC-OCV characteristic having a flat region in which a change rate of an open circuit voltage to a state of charge is equal to or less than a predetermined value, wherein:
a use mode of the secondary battery includes a consumption mode for consuming electric power stored in the secondary battery and a charging mode for charging the secondary battery; and
the method includes
acquiring a discharge current integrated amount that is an integrated value of current discharged from the secondary battery, from when a stage change in which a voltage change of the secondary battery is abrupt occurs until when the consumption mode ends in the consumption mode,
acquiring a charge current integrated amount that is an integrated value of current charged to the secondary battery, from when charging of the secondary battery is started until when the secondary battery is fully charged in the charging mode, and
calculating the full charge capacity of the secondary battery based on a storage amount of the secondary battery when the stage change occurs, the discharge current integrated amount, and the charge current integrated amount.
